(19) United States
(12) Patent Application Publication
(10) Pub. No.: US 2024/0063141 A1
(43) Pub. Date: Feb. 22, 2024

(54) SOLDER JOINT DESIGN FOR IMPROVED PACKAGE RELIABILITY

(71) Applicant: Micron Technology, Inc., Boise, ID (US)

(72) Inventors: Faxing Che, Singapore (SG); Yeow Chon Ong, Singapore (SG)

(21) Appl. No.: 17/891,535

(22) Filed: Aug. 19, 2022

(51) Int. Cl. H01L 23/00; H01L 23/498

(52) U.S. Cl. CPC H01L 23/562; H01L 23/49811; H01L 23/49838

(57) ABSTRACT

A semiconductor package can include a substrate having bonded thereto an array of solder joints. Each of the solder joints in the array can have a first surface area and a first shape. The semiconductor package can further include at least one differently-sized solder joint having a second surface area larger than the first surface area. The differently-sized solder joint can have a second shape different from the first shape. Other systems, methods and apparatuses are described.

### FIELD OF THE DISCLOSURE

Embodiments of the disclosure relate generally to semiconductor devices and packaging. More specifically, embodiments relate to solder joint and pad design for semiconductor devices.

### BACKGROUND

Integrated circuits (ICs) and other electronic components or devices can be packaged on a semiconductor package. ICs are mounted on a substrate. As semiconductor packages increase in size and complexity, these substrates can become thinner as more size is needed to accommodate silicon chip volume. This can increase the deformation and stress on solder joint interfaces due to the coefficient of thermal expansion (CTE) mismatch between packages and printed circuit boards (PCB) when packages are subjected to temperature cycling. These and other conditions can reduce package solder joint reliability (SJR). Furthermore, semiconductor package components can face other challenges such as drop impact, which also reduces SJR. There is a general need to improve SJR in electronic devices and components thereof.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates an example device in accordance with some examples of the present disclosure.

FIG. 2 illustrates a layout of joints that can be used in available systems.

FIG. 3 illustrates an example pad and joint layout that increases interfacial area between solder joints and pads in accordance with some aspects of the present disclosure.

FIG. 4A illustrates a joint design option comprising an L-shaped joint in accordance with some aspects of the present disclosure.

FIG. 4B illustrates a joint design option comprising a cross-shaped joint in accordance with some aspects of the present disclosure.

FIG. 4C illustrates a joint design option comprising a square-shaped joint in accordance with some aspects of the present disclosure.

FIG. 4D illustrates a second joint design option comprising a square-shaped joint in accordance with some aspects of the present disclosure.

FIG. 4E illustrates a joint design option comprising an L-shaped joint at a die corner and a second L-shaped joint opposite an IC chip placement in accordance with some aspects of the present disclosure.

FIG. 4F illustrates a joint design option comprising an L-shaped joint at a die corner and a second L-shaped joint in accordance with some aspects of the present disclosure.

FIG. 4G illustrates a joint design option comprising a square-shaped joint at a die corner and a second square-shaped joint in accordance with some aspects of the present disclosure.

FIG. 4H illustrates a joint design option comprising a triangle-shaped joint at a die corner and a second triangle-shaped joint in accordance with some aspects of the present disclosure.

FIG. 4I illustrates a joint design option comprising an cross-shaped joint at a die corner and a L-shaped joint in accordance with some aspects of the present disclosure.

FIG. 5 illustrates a flow diagram for a method of manufacture of an electronic device in accordance with aspects of the present disclosure.

FIG. 6 depicts a schematic of a computer system in which a semiconductor package according to examples may be implemented.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

As semiconductor packages become larger and larger, packages with relatively large silicon chip volume and thin substrate can experience increased deformation at the solder joint interface due to the coefficient of thermal expansion (CTE) mismatch between the package and printed circuit board (PCB) when the packages are subjected to thermal cycling on board (TCOB), which is usually a weak point of package solder joint reliability (SJR). Packages can also be subjected to drop impact and other challenges affecting SJR.

SJR performance can be improved by including additional solder joints with semiconductor packages to act as mechanical supports. In some examples, the additional solder joints can comprise “dummy” solder joints that provide additional mechanical support but do not couple electrical signals or power. The additional solder joints can be formed using solder balls or a solder paste. The additional solder joints of various shapes or sizes at various points on the semiconductor package where mechanical stress or other stress is anticipated. In some embodiments, additional solder joints can be added to a ball grid array (BGA), while in other embodiments additional solder joints can be added to a land grid array (LGA). Some semiconductor packages or electronic devices will include both BGA and LGA with either or both including additional solder joints as described herein.

By providing the additional solder joints (and bonding pads), solder joint area is increased between the semiconductor package and PCB, which helps to improve solder joint reliability under TCOB and/or drop impact dynamic loading conditions. The enlarged and uniquely shaped joints and pads are provided in locations identified by numerical simulation results, and the size and shape of the additional solder joints can also vary based on application as described later herein. The additional solder joints as described herein can increase the solder joint interface area, which increases cracking path length and helps to increase solder joint TCOB fatigue life.

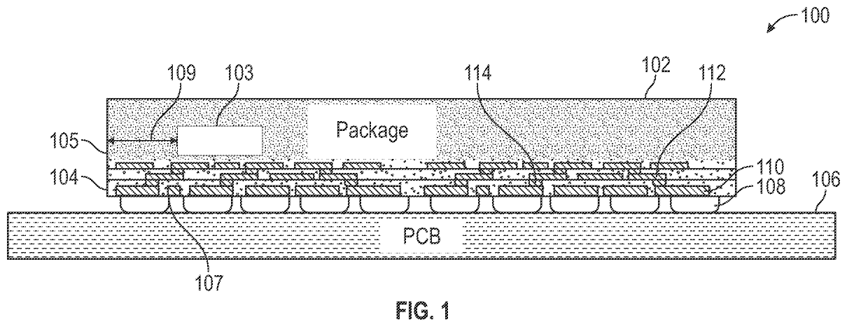

FIG. 1 illustrates an example device 100 in accordance with some examples of the present disclosure Device 100 may also be referred to as an electronic apparatus. Device 100 includes a semiconductor package 102, which is mounted on a substrate 104 to a printed circuit board (PCB) 106. The semiconductor package 102 can include, for example, integrated circuits (ICs, e.g., IC 103), memory devices, and any other electronic component or package of components. The substrate 104 can be formed by build-up layers comprised of dielectric material.

The PCB 106 can comprise a laminated structure of conductive and insulating layers. An array of solder joints 108 connects the PCB 106 to the package substrate 104. The array of solder joints 108 can comprise ball grid array (BGA) joints, land grid array (LGA) joints, although embodiments are not limited to BGA and LGA. Conductive pads 110 are provided to connect to the package 102 using traces 112, vias 114 or other features etched from one or more sheet layers of copper or other material laminated onto or between nonconductive layers of substrate 104. The PCB 106 can be single-sided (e.g., one copper layer can be provided), double-sided (e.g., two copper layers can be provided on either side of a nonconductive substrate) or multi-layer (outer and inner layers of copper, alternating with nonconductive layers).

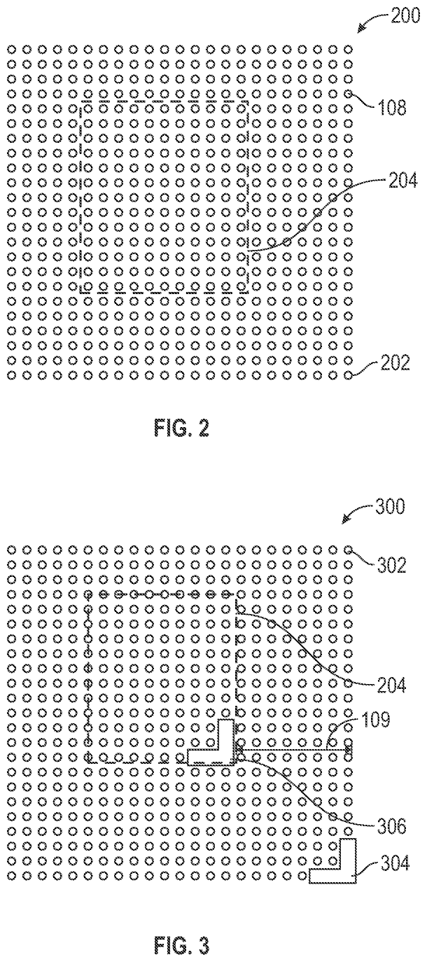

In some available systems, pads 110 and joints 108 are of uniform size, shape and distribution. FIG. 2 illustrates 200 a layout of joints 108 that can be used in available systems. The joints 108 can couple to PCB 106 (FIG. 1). The joints 108 can be evenly spaced and of uniform size, such that joints 108 at a corner 202 of the layout 200 are similarly sized and spaced as in other regions, for example a region 204 over which an integrated circuit of a semiconductor package is mounted (e.g., integrated circuit 103 within semiconductor package 102 (FIG. 1)).

In these and other example systems, cracks can propagate along an interface between the joints 108 and pads (e.g., pads 110 (FIG. 1)) leading to device failure. Cracks can also occur when the device or associated housings are dropped, subject to temperature extremes or temperature cycling, or other stress conditions.

To address these and other concerns, pads 110 (FIG. 1) can be provided with different designs and increased interfacial area with solder joints 108 (FIG. 1) that also have varied designs, shapes, and surface areas. FIG. 3 illustrates an example pad and joint layout 300 that increases interfacial area between solder joints and pads in accordance with some aspects of the present disclosure. Pad and joint layouts similar to layout 300 can help increase solder joint robustness and strength when the joints 108 and associated device 100 (FIG. 1) are subjected to shear or peeling stress. The solder joints can include, for example, land grid array (LGA) joints or ball grid array (BGA) joints, for example.

Referring still to FIG. 3, a semiconductor package substrate (e.g., the substrate 104 (FIG. 1)) can have bonded thereto an array of solder joints 302 similar to the array shown in FIG. 2, such that a solder joint 302 of the array of solder joints has a first surface area and a first shape. In FIG. 3, the shape is shown to be round, or circular, although other shapes can be provided in other embodiments. In addition, the substrate 104 can have bonded thereto at least one differently-sized solder joint 304, 306 having a second surface area larger than the first surface area. The at least one differently-sized solder joint 304, 306 can have a second shape different from the first shape. For example, as shown in FIG. 3, each of the differently-sized solder joints 304, 306 is provided in an “L” shape. In some example embodiments, a differently-sized solder joint 304, 306 has a surface area at least three times larger than the first surface area (e.g., three times larger than the surface area of the solder joint 302).

Referring to FIG. 1 in conjunction with FIG. 3, a semiconductor package (e.g., package 102 (FIG. 1)) can include an IC 103 bonded at a first surface 105 of the substrate 104. At least one differently-sized solder joint is included on a second surface 107 of the substrate opposite the first surface 105 and opposite the IC 103. The region 204 can illustrate portions of the second surface 107 that is opposite the IC 103 and at a corresponding location on the second surface that mirrors the placement of the IC 103 on the opposite surface. For example, the differently-sized solder joint 306 can be on the second surface of the substrate opposite IC chip, or in region 204 proximate the corresponding location on the second surface. In the examples, the differently-sized solder joint 306 can be at a corner of the region 204 as shown, although embodiments are not limited thereto. For example, when a corner of the IC 103 is about a first distance 109 from an edge of the substrate 104, the differently-sized solder joint 306 can be provided at a location about the same distance 109 from the edge of the substrate, although on the opposite surface of the substrate.

In some examples, such as the example shown in FIG. 3, at least two differently-sized solder joints 304, 306 are used. At least one differently-sized solder joint 306 can be included opposite the IC at, for example, a corner of region 204 as described above. At least one other differently-sized solder joint (e.g., solder joint 304) can be located at a corner of the substrate, e.g., adjacent to an edge of the substrate 104. Pads provided bonded to the differently-sized solder joints can comprising conductive pads that receive electrical signals, or pads that do not receive electrical signals (e.g., “dummy” pads).

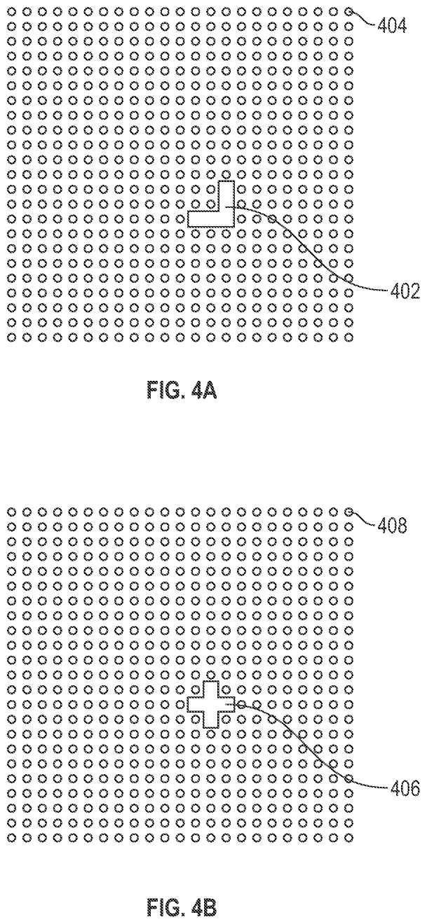

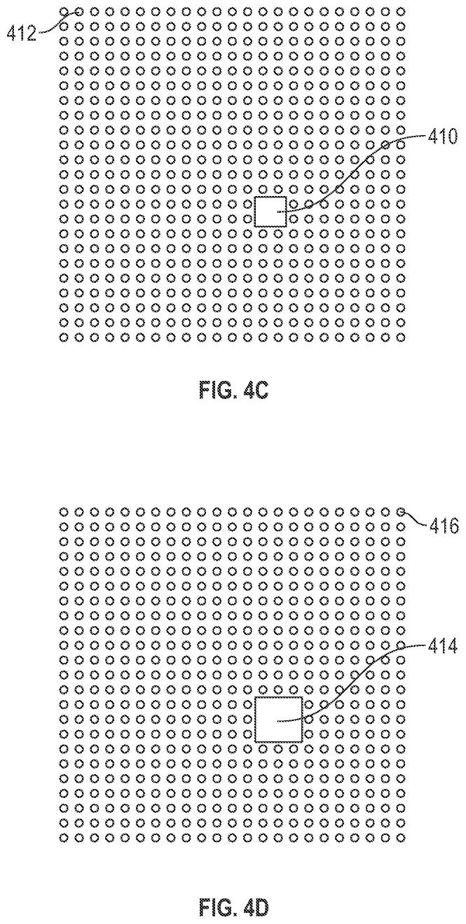

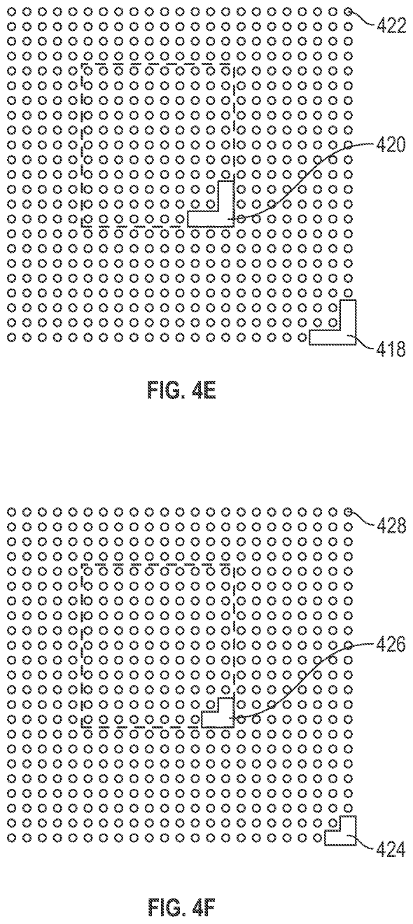

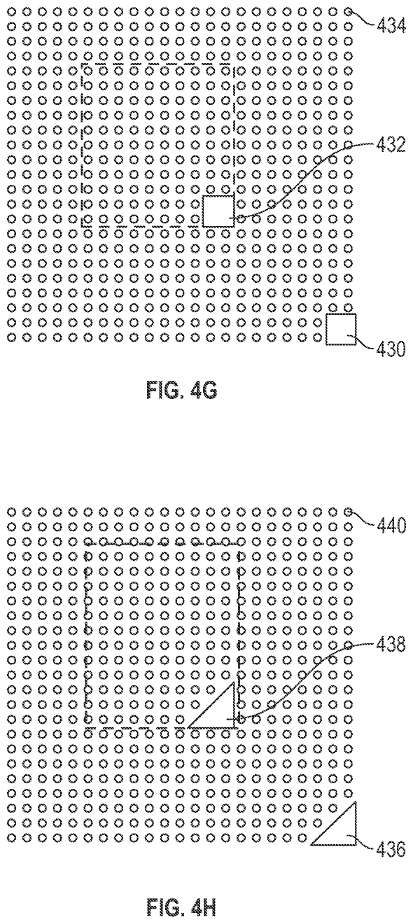

Other placements, sizes and shapes can be used for the differently-sized solder joints. For example, shapes of the differently-sized solder joints can comprise an L shape, a cross shape, a triangle shape, or a square shape, although embodiments are not limited to these shapes. Some joint design options are shown in FIG. 4A-4I below. As with embodiments described above, the joints can be BGA or LGA joints, or other types of joints.

FIG. 4A illustrates a joint design option comprising an L-shaped joint 402 in accordance with some aspects of the present disclosure. The joint 402 can be at least five times larger in surface area than conventional joints 404. The joint 402 is illustrated within an interior region of the joint layout but embodiments are not limited to the joint 402 being within the interior region. Other placements for the joint 402 can be determined as described later herein. FIG. 4B illustrates a joint design option comprising a cross-shaped joint 406 in accordance with some aspects of the present disclosure. The joint 406 can be at least five times larger in surface area than conventional joints 408. The joint 406 is illustrated within an interior region of the joint layout but embodiments are not limited to the joint 406 being within the interior region. Other placements for the joint 406 can be determined as described later herein.

FIG. 4C illustrates a joint design option comprising a square-shaped joint 410 in accordance with some aspects of the present disclosure. The joint 410 can be at least four times larger in surface area than conventional joints 412. The joint 410 is illustrated within an interior region of the joint layout but embodiments are not limited to the joint 410 being within the interior region. Other placements for the joint 410 can be determined as described later herein. FIG. 4D illustrates a second joint design option comprising a square-shaped joint 414 in accordance with some aspects of the present disclosure. The joint 414 can be at least nine times larger in surface area than conventional joints 416. The joint 414 is illustrated within an interior region of the joint layout but embodiments are not limited to the joint 414 being within the interior region. Other placements for the joint 414 can be determined as described later herein.

FIG. 4E illustrates a joint design option comprising an L-shaped joint 420 at a die corner and a second L-shaped joint 418 at a package or substrate corner in accordance with some aspects of the present disclosure. The second L-shaped joint 420 is shown at a corner within dashed lines that represent an area of a surface opposite the second L-shaped joint 420 at which an IC may be mounted as described earlier herein with respect to FIG. 2 and FIG. 3. One or both of the joints 418 and 420 can be at least five times larger in surface area than conventional joints 422. Other placements and sizes for the joints 418 and 420 can be determined as described later herein.

FIG. 4F illustrates a joint design option comprising an L-shaped joint 424 at a package (or substrate) corner and a second L-shaped joint 426 opposite an IC chip placement in accordance with some aspects of the present disclosure. The second L-shaped joint 426 is shown at a corner within dashed lines that represent an area of a surface opposite the second L-shaped joint 426 at which an IC may be mounted as described earlier herein with respect to FIG. 2 and FIG. 3. One or both of the joints 424 and 426 can be at least three times larger in surface area than conventional joints 428. Other placements and sizes for the joints 424 and 426 can be determined as described later herein.

FIG. 4G illustrates a joint design option comprising a square-shaped joint 430 at a package (or substrate) corner and a second square-shaped joint 432 opposite an IC chip placement in accordance with some aspects of the present disclosure. The second square-shaped joint 432 is shown at a corner within dashed lines that represent an area of a surface opposite the second square-shaped joint 432 at which an IC may be mounted as described earlier herein with respect to FIG. 2 and FIG. 3. One or both of the joints 430 and 432 can be at least four times larger in surface area than conventional joints 434. Other placements and sizes for the joints 430 and 432 can be determined as described later herein.

FIG. 4H illustrates a joint design option comprising a triangle-shaped joint 436 at a package (or substrate) corner and a second triangle-shaped joint 438 opposite an IC chip placement in accordance with some aspects of the present disclosure. The second triangle-shaped joint 438 is shown at a corner within dashed lines that represent an area of a surface opposite the second triangle-shaped joint 438 at which an IC may be mounted as described earlier herein with respect to FIG. 2 and FIG. 3. One or both of the joints 436 and 438 can be at least six times larger in surface area than conventional joints 440. Other placements and sizes for the joints 436 and 438 can be determined as described later herein.

FIG. 4I illustrates a joint design option comprising an L-shaped joint 442 at a package (or substrate) corner and a cross-shaped joint 444 opposite an IC chip placement in accordance with some aspects of the present disclosure. The cross-shaped joint 444 is shown at a corner within dashed lines that represent an area of a surface opposite the cross-shaped joint 444 at which an IC may be mounted as described earlier herein with respect to FIG. 2 and FIG. 3. One or both of the joints 442 and 444 can be at least three times, or at least five times larger in surface area than conventional joints 446. Other placements and sizes for the joints 442 and 444 can be determined as described later herein.

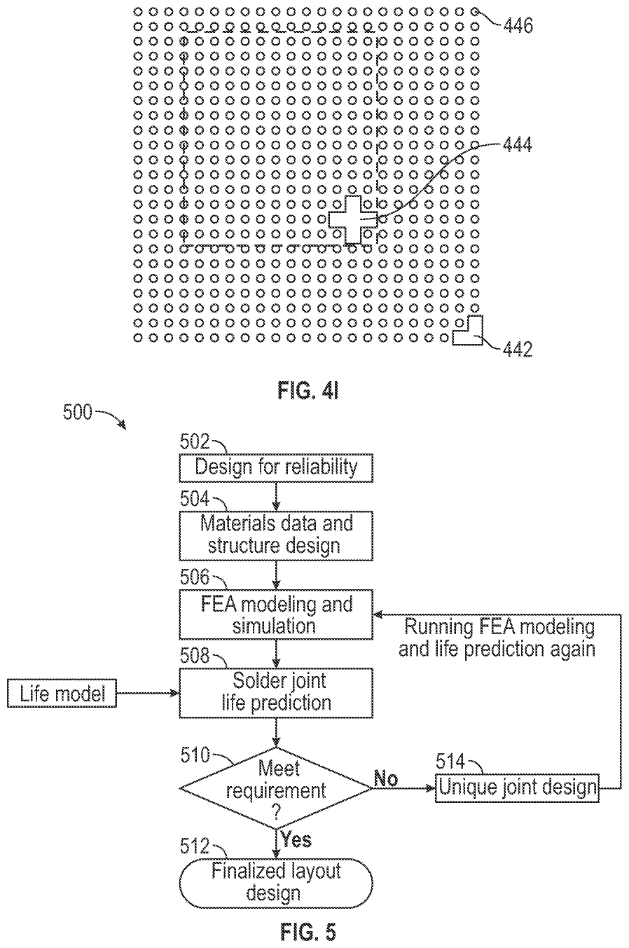

FIG. 5 illustrates a flow diagram for a method 500 of manufacture of an electronic device in accordance with aspects of the present disclosure. The design of joint location can be determined by finite element analysis (FEA) simulation, although embodiments are not limited thereto. Subsequent to operation 502 for package design for reliability and materials data and structure design in operation 504, the method 500 can include finite element analysis (FEA) modeling and simulation in operation 506 to predict a location on a substrate or PCB of the electronic device at which mechanical stress is at or above a failure threshold location. These predictions can be used to determine the number, size, shape and placement of the differently-sized pads and joints described above with reference to FIG. 3 and FIGS. 4A-4I. In some aspects, tradeoffs and adjustments can be made for BGA layouts, which have a higher solder standoff height and therefore slightly increased solder joint life in contrast to LGA layouts which can be more flexible and easily-adapted to different solder joint and pad shapes.

In operation 508, solder joint life can be predicted based on models and other data provided to the manufacturing process. If requirements for solder joint life is met, in operation 510, the solder joint and pad layout are finalized in operation 512, at which point a joint structure is provided comprising a conductive pad and a solder joint at or proximate one or more predicted locations to improve solder joint reliability. In some aspects, the joint structure can have a surface area based on a magnitude of predicted mechanical stress at the predicted one or more locations. If solder joint reliability criteria are not met, in operation 514 the joint and pad design can be adjusted to improve mechanical reliability and other reliability. In some aspects, additional FEAs can be performed on the electronic device subsequent to providing the joint structure. The location, size, etc. of the joint structure can then be verified and/or adjusted based on results of the second FEA and additional FEAs.

In aspects of the present disclosure, joints are prepared by solder stencil printing or electrical plating and formed by reflow, although embodiments are not limited to these methods for preparing and placing solder joints. The differently-sized and shaped pads and solder joints according to aspects of the disclosure can improve solder joint temperature cycling life compared to evenly-spaced and sized joints and pads, to provide double or more of the temperature cycling life. Different combinations, placement, shape, size and number of solder joints and pads can be placed depending on the type of the electronic device in which the semiconductor package 102 will be used.

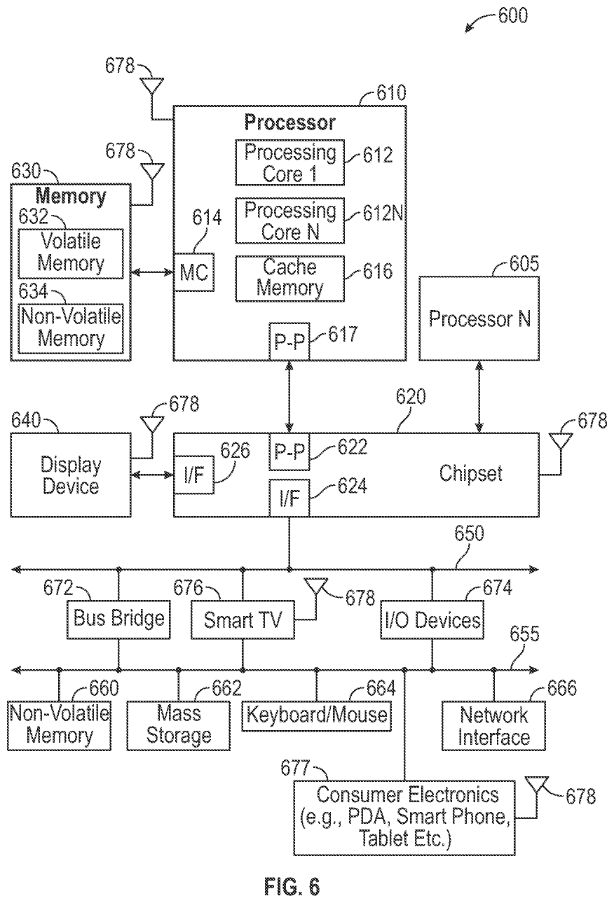

FIG. 6 depicts a schematic of a computer system as an example. FIG. 6 illustrates a system level diagram, depicting an example of an electronic device (e.g., system) that may include semiconductor packages having arrays of solder joints including differently-sized joints as described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMAXs, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display device 640 may be, for example, a liquid crystal display (LCD), a light emitting diode (LED) array, an organic light emitting diode (OLED) array, or any other form of the visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, storage medium 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMAX, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

The above detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Although specific embodiments have been illustrated and described herein, any arrangement that is calculated to achieve the same purpose may be substituted for the specific embodiments shown. Various embodiments can use permutations and/or combinations of embodiments described herein. The above description is intended to be illustrative, and not restrictive, and that the phraseology or terminology employed herein is for the purpose of description.

What is claimed is:

1. A semiconductor package comprising:
a substrate having bonded thereto:
an array of solder joints, a solder joint of the array of solder joints having a first surface area and a first shape; and
at least one differently-sized solder joint having a second surface area larger than the first surface area, the at least one differently-sized solder joint having a second shape different from the first shape.

2. The semiconductor package of claim 1, wherein the at least one differently-sized solder joint has a surface area at least three times larger than the first surface area.

3. The semiconductor package of claim 1, wherein the semiconductor package includes an integrated circuit (IC) mounted on a first surface of the substrate, and wherein the at least one differently-sized solder joint is included on a second surface of the substrate opposite the first surface and opposite the IC.

4. The semiconductor package of claim 3, wherein a corner of the IC is about a first distance from an edge of the substrate, and wherein the at least one differently-sized solder joint is provided at a location about the first distance from the edge of the substrate.

5. The semiconductor package of claim 3, further comprising at least two differently-sized solder joints, and wherein the IC is mounted at a first location on the substrate, and wherein at least one of the at least two differently-sized solder joints is included on a second surface of the substrate opposite the first surface and proximate the first location.

6. The semiconductor package of claim 1, wherein the at least one differently-sized solder joint is included adjacent an edge of the substrate.

7. The semiconductor package of claim 6, wherein the at least one differently-sized solder joint is included at a corner region of the substrate.

8. The semiconductor package of claim 1, wherein the second shape comprises one of an L shape, a cross shape, a triangle shape, or a square shape.

9. The semiconductor package of claim 1, wherein the array of solder joints comprises a land grid array (LGA) structure.

10. The semiconductor package of claim 1, wherein the array of solder joints comprises a ball grid array (BGA) structure.

11. The semiconductor package of claim 1, further comprising a conductive pad bonded to the at least one differently-sized solder joint, wherein the conductive pad receives electrical signals.

12. The semiconductor package of claim 1, further comprising a conductive pad bonded to the at least one differently-sized solder joint, wherein the conductive pad is a dummy pad such that the conductive pad does not receive electrical signals.

13. An electronic device comprising:
a package substrate; and
a printed circuit board (PCB) coupled to the package substrate, at least one of the package substrate and the PCB having bonded thereto:
an array of solder joints, a solder joint of the array of solder joints having a first surface area and a first shape; and
at least one differently-sized solder joint having a second surface area larger than the first surface area, the at least one differently-sized solder joint having a second shape different from the first shape.

14. The electronic device of claim 13, wherein the package substrate includes an integrated circuit (IC) bonded at a first surface of the package substrate, and wherein the at least one differently-sized solder joint is included on a second surface of the package substrate opposite the first surface and opposite the IC.

15. The electronic device of claim 14, further comprising a conductive pad bonded to the at least one differently-sized solder joint, wherein the conductive pad transmits electrical signals between the IC and the PCB.

16. The electronic device of claim 14, further comprising a conductive pad bonded to the at least one differently-sized solder joint, wherein the conductive pad is a dummy pad such that the conductive pad does not receive electrical signals.

17. The electronic device of claim 14, wherein the array comprises a land grid array (LGA) structure.

18. The electronic device of claim 13, wherein the second shape comprises one of an L shape, a cross shape or a triangle shape, and wherein the second surface area is at least three times larger than the first surface area.

19. A method of manufacture of an electronic device, the method comprising:
predicting a location on a substrate or printed circuit board (PCB) of the electronic device at which mechanical stress is at or above a failure threshold; and
providing a joint structure comprising a conductive pad and a solder joint at or proximate the location, the joint structure having a surface area based on a magnitude of predicted mechanical stress at the location.

20. The method of claim 19, wherein the joint structure further includes shape characteristics based on a type of the electronic device.

21. The method of claim 19, wherein the predicting comprises predicting based on finite element analysis (FEA).

22. The method of claim 21, further comprising:
performing a second FEA on the electronic device subsequent to providing the joint structure; and
verifying the location of the joint structure based on results of the second FEA.
